(19) United States
(12) Patent Application Publication
(10) Pub. No.: US 2024/0251849 A1
(43) Pub. Date: Aug. 1, 2024

(54) AEROSOL-GENERATING DEVICE HAVING PUFF RECOGNITION FUNCTION AND PUFF RECOGNITION METHOD THEREOF

(71) Applicant: KT&G CORPORATION, Daejeon (KR)

(72) Inventors: Seung Won LEE, Gyeonggi-do (KR); Dong Sung KIM, Seoul (KR); Yong Hwan KIM, Gyeonggi-do (KR); Seok Su JANG, Daejeon (KR); Dae Nam HAN, Seoul (KR)

(73) Assignee: KT&G CORPORATION, Daejeon (KR)

(21) Appl. No.: 18/289,695

(22) PCT Filed: Apr. 8, 2022
(86) PCT No.: PCT/KR2022/005101

§ 371 Date: Nov. 6, 2023

(30) Foreign Application Priority Data
May 28, 2021 (KR) 10-2021-0069541

(51) Int. Cl. A24F 40/20; A24F 40/51; A24F 40/53

(52) U.S. Cl. CPC A24F 40/20; A24F 40/51; A24F 40/53

(57) ABSTRACT

An aerosol-generating device having a puff recognition function includes a temperature sensor configured to sense a temperature change of an airflow path formed inside the aerosol-generating device, and a controller configured to compare first information that varies depending on the temperature change with preset second information, and determine whether a user's puff occurred on a comparison result.

### TECHNICAL FIELD

The present disclosure relates to an aerosol-generating device having a puff recognition function and a puff recognition method thereof, and more particularly, to an aerosol-generating device capable of recognizing and counting user's puffs and a puff recognition method of the aerosol-generating device.

### BACKGROUND ART

Recently, the demand for alternative methods to overcome the disadvantages of traditional cigarettes has increased. For example, there is growing demand for an aerosol-generating device which generates an aerosol by heating an aerosol generating article (e.g., cigarette) including an aerosol generating material without combustion. Accordingly, researches on a heating-type aerosol-generating device has been actively conducted.

### DISCLOSURE

### Technical Problem

In general, an aerosol-generating device provides a smoking experience to a user through a predetermined number of puffs after power is turned on, and temporarily enters a standby mode or a charging mode when the predetermined number is exhausted. In general, heating-type aerosol-generating devices generate a low quality aerosol when an aerosol generating material is heated for an excessively long time, which is likely to happen due to their structural characteristics. Thus, in order to provide a user with an aerosol having consistent quality, it is desirable to accurately count the number of puffs of the user and temporarily stop heating a heater based on the counted number of puffs.

An objective of the present disclosure is to provide an aerosol-generating device capable of accurately recognizing a user's puff.

### Technical Solution

An aerosol-generating device according to an embodiment of the present disclosure has a puff recognition function and includes a temperature sensor that senses a temperature change of an airflow path formed inside the aerosol-generating device, and a controller that compares first information that varies depending on the temperature change with preset second information, and determines whether a user's puff occurred based on a comparison result.

A puff recognition method of an aerosol-generating device, according to an embodiment of the present disclosure, includes: sensing, by a temperature sensor, a temperature change of air in an airflow path formed inside the aerosol-generating device; comparing, by a first module, first information that varies depending on the temperature change with preset second information; and determining, by the controller, whether a puff has been generated by a user based on the result of the comparing.

### Advantageous Effects

According to the present disclosure, the puff (i.e., inhalation) may be accurately recognized regardless of the unique characteristics of a user's inhalation action.

Furthermore, according to the present disclosure, an aerosol having consistent quality may be provided to a user through accurate puff counting.

### DESCRIPTION OF DRAWINGS

FIGS. 1 and 2 are views illustrating examples in which a cigarette is inserted into an aerosol-generating device.

FIG. 3 is a view illustrating another example in which a cigarette is inserted into an aerosol-generating device.

FIG. 4 is a view illustrating an example of a cigarette.

FIG. 5 is a view illustrating another example of a cigarette.

FIG. 6 is a view illustrating an example of a double medium cigarette used in the aerosol-generating device of FIG. 3.

FIG. 7 is a perspective view of an example of an aerosol-generating device according to an embodiment of the present disclosure.

FIG. 8 is a side view of the aerosol-generating device of FIG. 7.

FIG. 9 is a diagram illustrating an example of a puff recognition circuit included in an aerosol-generating device according to an embodiment of the present disclosure.

FIG. 10 is a schematic view illustrating a cross-section of an aerosol-generating device according to an embodiment of the present disclosure.

FIG. 11 is a perspective view of another example of an aerosol-generating device according to an embodiment of the present disclosure.

FIG. 12 is a diagram for intuitively illustrating the puff recognition circuit described with reference to FIGS. 9 to 11.

FIG. 13 is a flowchart illustrating an example of a puff recognition method of an aerosol-generating device according to an embodiment of the present disclosure.

### BEST MODE

According to an aspect of the present disclosure, an aerosol-generating device having a puff recognition function includes: a temperature sensor configured to sense a temperature change of an airflow path formed inside the aerosol-generating device; and a controller configured to compare first information that varies depending on the temperature change with preset second information, and determine whether a user's puff occurred based on a comparison result.

The first information and the second information may change in proportion to a driving voltage of a first module included in the aerosol-generating device.

The first module may include a comparator.

The first information may include an input voltage of a positive (+) terminal of the comparator, and the second information may include an input voltage of a negative (−) terminal of the comparator, wherein the controller may determine that the user's puff occurred, based on a signal that is output from an output terminal of the comparator when the input voltage of the positive (+) terminal is greater than the input voltage of the negative (−) terminal.

The first information may include a voltage value that changes according to a temperature change of the airflow path.

The temperature sensor may include a temperature change sensing portion that senses the temperature change, and a variable resistor having resistance that is changed in proportion to the temperature change.

The temperature sensor may include a temperature change sensing portion that senses the temperature change, and a variable resistor having resistance that is changed in inverse proportion to the temperature change.

The second information may be determined based on the fixed resistance values of two resistors.

The first information may be calculated based on temperature changes sensed by two or more temperature sensors.

The temperature sensor may selectively sense a temperature change exceeding a preset value.

According to an aspect of the present disclosure, a puff recognition method of an aerosol-generating device includes: sensing, by a temperature sensor, a temperature change of an airflow path formed inside the aerosol-generating device; comparing, by a first module, first information that varies depending on the temperature change with preset second information when the temperature change is sensed; and determining, by the controller, whether a puff has been generated by a user based on the result of the comparing.

The first information and the second information may change in proportion to a driving voltage of a first module included in the aerosol-generating device.

The first module may include a comparator.

The first information may include an input voltage of a positive (+) terminal of the comparator, and the second information may include an input voltage of a negative (−) terminal of the comparator, wherein the determining of whether the puff has been generated may include: determining that the user's puff occurred, based on a signal that is output from an output terminal of the comparator when the input voltage of the positive (+) terminal is greater than the input voltage of the negative (−) terminal.

The first information may be calculated based on temperature changes sensed by two or more temperature sensors.

### MODE FOR INVENTION

With respect to the terms used to describe in the various embodiments, the general terms which are currently and widely used are selected in consideration of functions of structural elements in the various embodiments of the present disclosure. However, meanings of the terms can be changed according to intention, a judicial precedence, the appearance of a new technology, and the like. In addition, in certain cases, a term which is not commonly used can be selected. In such a case, the meaning of the term will be described in detail at the corresponding portion in the description of the present disclosure. Therefore, the terms used in the various embodiments of the present disclosure should be defined based on the meanings of the terms and the descriptions provided herein.

In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and operation and can be implemented by hardware components or software components and combinations thereof.

Hereinafter, the present disclosure will now be described more fully with reference to the accompanying drawings, in which exemplary embodiments of the present disclosure are shown such that one of ordinary skill in the art may easily work the present disclosure. The disclosure may, however, be embodied in many different forms and should not be construed as being limited to the embodiments set forth herein.

Hereinafter, embodiments of the present disclosure will be described in detail with reference to the drawings.

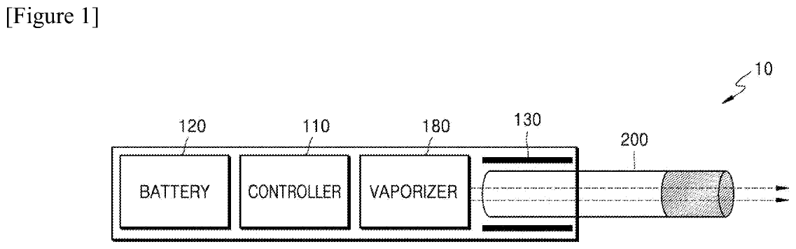

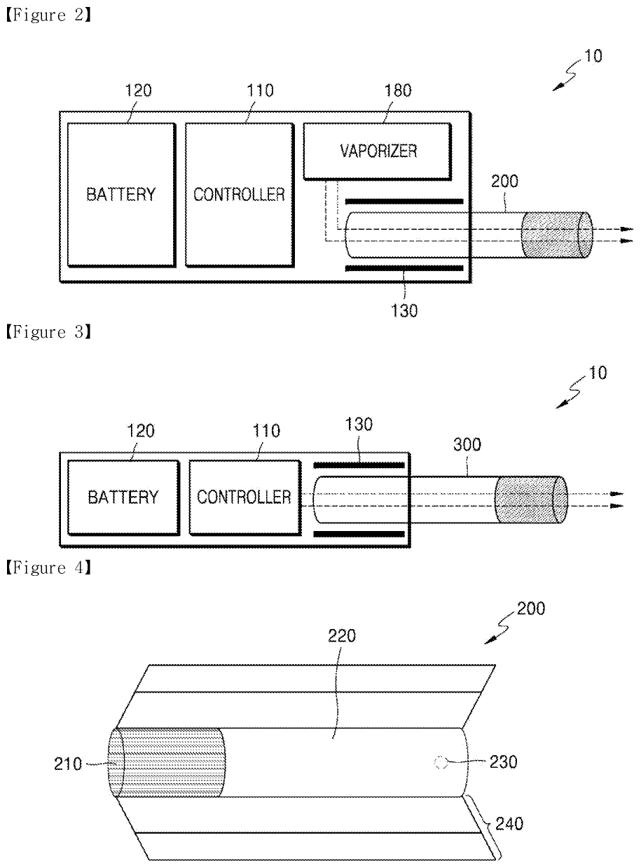

FIGS. 1 and 2 are diagrams showing examples in which an aerosol-generating article is inserted into an aerosol-generating device.

Referring to FIGS. 1 and 2, the aerosol-generating device 10 may include a battery 120, a controller 110, a heater 130 and a vaporizer 180. Also, cigarette 200 may be inserted into an inner space of the aerosol-generating device 10.

FIGS. 1 and 2 illustrate components of the aerosol-generating device 10, which are related to the present embodiment. Therefore, it will be understood by one of ordinary skill in the art related to the present embodiment that other general-purpose components may be further included in the aerosol-generating device 10, in addition to the components illustrated in FIGS. 1 and 2.

Also, FIGS. 1 and 2 illustrate that the aerosol-generating device 10 includes the heater 130. However, as necessary, the heater 130 may be omitted.

FIG. 1 illustrates that the battery 120, the controller 110, and the heater 130 are arranged in series. Also, FIGS. 1 and 2 illustrates that the vaporizer 180 and the heater 130 are arranged in parallel. However, the internal structure of the aerosol-generating device 10 is not limited to the structures illustrated in FIGS. 1 and 2. In other words, according to the design of the aerosol-generating device 10, the battery 120, the controller 110, the heater 130, and the vaporizer 180 may be differently arranged.

When cigarette 200 is inserted into the aerosol-generating device 10, the aerosol-generating device 10 may operate the vaporizer 180 to generate aerosol from the vaporizer 180. The aerosol generated by the vaporizer 180 is delivered to a user by passing through cigarette 200. A description of the vaporizer 180 will be given in more detail below.

The battery 120 may supply power to be used for the aerosol-generating device 10 to operate. For example, the battery 120 may supply power to heat the heater 130 or the vaporizer 180, and may supply power for operating the controller 110. Also, the battery 120 may supply power for operations of a display, a sensor, a motor, etc. mounted in the aerosol-generating device 10.

The controller 110 may generally control operations of the aerosol-generating device 10. In detail, the controller 110 may control not only operations of the battery 120, the heater 130, and the vaporizer 180, but also operations of other components included in the aerosol-generating device 10. Also, the controller 110 may check a state of each of the components of the aerosol-generating device 10 to determine whether or not the aerosol-generating device 10 is able to operate.

The controller 110 may include at least one processor. A processor can be implemented as an array of a plurality of logic gates or can be implemented as a combination of a general-purpose microprocessor and a memory in which a program executable in the microprocessor is stored. It will be understood by one of ordinary skill in the art that the processor can be implemented in other forms of hardware.

The heater 130 may be heated by the power supplied from the battery 120. For example, when cigarette 200 is inserted into the aerosol-generating device 10, the heater 130 may be located outside cigarette 200. Thus, the heated heater 130 may increase a temperature of an aerosol generating material in cigarette 200.

The heater 130 may include an electro-resistive heater. For example, the heater 130 may include an electrically conductive track, and the heater 130 may be heated when currents flow through the electrically conductive track. However, the heater 130 is not limited to the example described above and may include all heaters which may be heated to a desired temperature. Here, the desired temperature may be pre-set in the aerosol-generating device 10 or may be set by a user.

As another example, the heater 130 may include an induction heater. In detail, the heater 130 may include an electrically conductive coil for heating an aerosol-generating article in an induction heating method, and cigarette may include a susceptor which may be heated by the induction heater.

In FIGS. 1 and 2, the heater 130 is illustrated as being disposed outside the cigarette 200, but is not limited thereto. For example, the heater 130 may include a tube-type heating element, a plate-type heating element, a needle-type heating element, or a rod-type heating element, and may heat the inside or the outside of cigarette 200, according to the shape of the heating element.

Also, the aerosol-generating device 10 may include a plurality of heaters 130. Here, the plurality of heaters 130 may be inserted into cigarette 200 or may be arranged outside cigarette 200. Also, some of the plurality of heaters 130 may be inserted into cigarette 200 and the others may be arranged outside cigarette 200. In addition, the shape of the heater 130 is not limited to the shapes illustrated in FIGS. 1 and 2, and may include various shapes.

The vaporizer 180 may generate aerosol by heating a liquid composition and the generated aerosol may pass through cigarette 200 to be delivered to a user. In other words, the aerosol generated via the vaporizer 180 may move along an air flow passage of the aerosol-generating device 10 and the air flow passage may be configured such that the aerosol generated via the vaporizer 180 passes through cigarette 200 to be delivered to the user.

For example, the vaporizer 180 may include a liquid storage, a liquid delivery element, and a heating element, but it is not limited thereto. For example, the liquid storage, the liquid delivery element, and the heating element may be included in the aerosol-generating device 10 as independent modules.

The liquid storage may store a liquid composition. For example, the liquid composition may be a liquid including a tobacco-containing material having a volatile tobacco flavor component, or a liquid including a non-tobacco material. The liquid storage may be formed to be detachable from the vaporizer 180 or may be formed integrally with the vaporizer 180.

For example, the liquid composition may include water, a solvent, ethanol, plant extract, spices, flavorings, or a vitamin mixture. The spices may include menthol, peppermint, spearmint oil, and various fruit-flavored ingredients, but are not limited thereto. The flavorings may include ingredients capable of providing various flavors or tastes to a user. Vitamin mixtures may be a mixture of at least one of vitamin A, vitamin B, vitamin C, and vitamin E, but are not limited thereto. Also, the liquid composition may include an aerosol forming substance, such as glycerin and propylene glycol.

The liquid delivery element may deliver the liquid composition of the liquid storage to the heating element. For example, the liquid delivery element may be a wick such as cotton fiber, ceramic fiber, glass fiber, or porous ceramic, but is not limited thereto.

The heating element is an element for heating the liquid composition delivered by the liquid delivery element. For example, the heating element may be a metal heating wire, a metal hot plate, a ceramic heater, or the like, but is not limited thereto. In addition, the heating element may include a conductive filament such as nichrome wire and may be positioned as being wound around the liquid delivery element. The heating element may be heated by a current supply and may transfer heat to the liquid composition in contact with the heating element, thereby heating the liquid composition. As a result, aerosol may be generated.

For example, the vaporizer 180 may be referred to as a cartomizer or an atomizer, but it is not limited thereto.

The aerosol-generating device 10 may further include general-purpose components in addition to the battery 120, the controller 110, the heater 130, and the vaporizer 180. For example, the aerosol-generating device 10 may include a display capable of outputting visual information and/or a motor for outputting haptic information. Also, the aerosol-generating device 10 may include at least one sensor (a puff sensor, a temperature sensor, an aerosol-generating article insertion detecting sensor, etc.). Also, the aerosol-generating device 10 may be formed as a structure that, even when cigarette 200 is inserted into the aerosol-generating device 10, may introduce external air or discharge internal air.

Although not illustrated in FIGS. 1 and 2, the aerosol-generating device 10 and an additional cradle may form together a system. For example, the cradle may be used to charge the battery 120 of the aerosol-generating device 10. Alternatively, the heater 130 may be heated when the cradle and the aerosol-generating device 10 are coupled to each other.

Cigarette 200 may be similar to a general combustive cigarette. For example, cigarette 200 may be divided into a first portion including an aerosol generating material and a second portion including a filter, etc. Alternatively, the second portion of cigarette 200 may also include an aerosol generating material. For example, an aerosol generating material made in the form of granules or capsules may be inserted into the second portion.

The entire first portion may be inserted into the aerosol-generating device 10, and the second portion may be exposed to the outside. Alternatively, only a portion of the first portion may be inserted into the aerosol-generating device 10, or the entire first portion and a portion of the second portion may be inserted into the aerosol-generating device 10. The user may puff aerosol while holding the second portion by the mouth of the user. In this case, the aerosol is generated by the external air passing through the first portion, and the generated aerosol passes through the second portion and is delivered to the user's mouth.

For example, the external air may flow into at least one air passage formed in the aerosol-generating device 10. For example, opening and closing of the air passage and/or a size of the air passage formed in the aerosol-generating device 10 may be adjusted by the user. Accordingly, the amount and the quality of smoking may be adjusted by the user. As another example, the external air may flow into cigarette 200 through at least one hole formed in a surface of cigarette 200.

FIG. 3 is a view illustrating another example in which a cigarette is inserted into an aerosol-generating device 10.

When compared with the aerosol-generating device 10 described with reference to FIGS. 1 and 2, the aerosol-generating device 10 shown in FIG. 3 does not include the vaporizer 180. Instead, an element performing the function of the vaporizer 180 may be included in a double medium cigarette 300.

When the double medium cigarette 300 is inserted into the aerosol-generating device 10 shown in FIG. 3, the aerosol-generating device 10 may generate an aerosol, which may be inhaled by a user, by externally heating the double medium cigarette 300. The double medium cigarette 300 will be described in more detail below with reference to FIG. 6.

Hereinafter, the examples of cigarette 200 will be described with reference to FIG. 4.

FIG. 4 illustrates an example of the cigarette 200.

Referring to FIG. 4, cigarette 200 may include a tobacco rod 210 and a filter rod 220. The first portion described above with reference to FIGS. 1 and 2 may include the tobacco rod 210, and the second portion may include the filter rod 220.

FIG. 4 illustrates that the filter rod 220 includes a single segment. However, the filter rod 220 is not limited thereto. In other words, the filter rod 220 may include a plurality of segments. For example, the filter rod 220 may include a first segment configured to cool an aerosol and a second segment configured to filter a certain component included in the aerosol. Also, as necessary, the filter rod 220 may further include at least one segment configured to perform other functions.

Cigarette 200 may be packaged using at least one wrapper 240. The wrapper 240 may have at least one hole through which external air may be introduced or internal air may be discharged. For example, cigarette 200 may be packaged by one wrapper 240. As another example, cigarette 200 may be doubly packaged by two or more wrappers 240. For example, the tobacco rod 210 may be packaged by a first wrapper 241, and the filter rod 220 may be packaged by wrappers. In addition, the tobacco rod 210 and the filter rod 220 wrapped by an individual wrapper may be combined, and the entire cigarette 200 may be repackaged by the third wrapper. When each of the tobacco rod 210 or the filter rod 220 includes a plurality of segments, each segment may be packaged by wrappers. In addition, the entire cigarette 200 in which segments wrapped by individual wrappers are combined may be repackaged by another wrapper.

The tobacco rod 210 may include an aerosol generating material. For example, the aerosol generating material may include at least one of glycerin, propylene glycol, ethylene glycol, dipropylene glycol, diethylene glycol, triethylene glycol, tetraethylene glycol, and oleyl alcohol, but it is not limited thereto. Also, the tobacco rod 210 may include other additives, such as flavors, a wetting agent, and/or organic acid. Also, the tobacco rod 210 may include a flavored liquid, such as menthol or a moisturizer, which is injected to the tobacco rod 210.

The tobacco rod 210 may be manufactured in various forms. For example, the tobacco rod 210 may be formed as a sheet or a strand. Also, the tobacco rod 210 may be formed as a pipe tobacco, which is formed of tiny bits cut from a tobacco sheet. Also, the tobacco rod 210 may be surrounded by a heat conductive material. For example, the heat conductive material may be, but is not limited to, a metal foil such as aluminum foil. For example, the heat conductive material surrounding the tobacco rod 210 may uniformly distribute heat transmitted to the tobacco rod 210, and thus, the heat conductivity applied to the tobacco rod may be increased and taste of the tobacco may be improved. Also, the heat conductive material surrounding the tobacco rod 210 may function as a susceptor heated by the induction heater. Here, although not illustrated in the drawings, the tobacco rod 210 may further include an additional susceptor, in addition to the heat conductive material surrounding the tobacco rod 210.

The filter rod 220 may include a cellulose acetate filter. Shapes of the filter rod 220 are not limited. For example, the filter rod 220 may include a cylinder-type rod or a tube-type rod having a hollow inside. Also, the filter rod 220 may include a recess-type rod. When the filter rod 220 includes a plurality of segments, at least one of the plurality of segments may have a different shape.

The filter rod 220 may be formed to generate flavors. For example, a flavoring liquid may be injected onto the filter rod 220, or an additional fiber coated with a flavoring liquid may be inserted into the filter rod 220.

Also, the filter rod 220 may include at least one capsule 230. Here, the capsule 230 may generate a flavor or an aerosol. For example, the capsule 230 may have a configuration in which a liquid containing a flavoring material is wrapped with a film. For example, the capsule 230 may have a spherical or cylindrical shape, but is not limited thereto.

When the filter rod 220 includes a segment configured to cool the aerosol, the cooling segment may include a polymer material or a biodegradable polymer material. For example, the cooling segment may include pure polylactic acid alone, but the material for forming the cooling segment is not limited thereto. In some embodiments, the cooling segment may include a cellulose acetate filter having a plurality of holes. However, the cooling segment is not limited to the above-described example and is not limited as long as the cooling segment cools the aerosol.

Meanwhile, although not shown in FIG. 4, the cigarette 200 according to an embodiment may further include a front-end filter. The front-end filter may be located on one side of the tobacco rod 210 which is opposite to the filter rod 220. The front-end filter may prevent the tobacco rod 210 from being detached outwards and prevent the liquefied aerosol from flowing from the tobacco rod 210 into the aerosol-generating device (100 of FIGS. 1 and 3), during smoking.

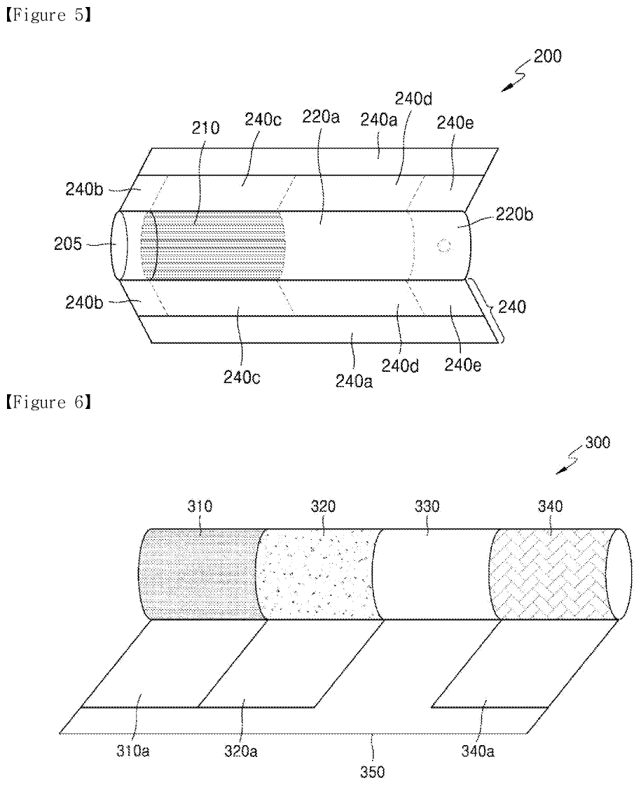

FIG. 5 is a view illustrating another example of the cigarette 200.

Referring to FIG. 5, the cigarette 200 may have a structure in which a cross tube 205, a tobacco rod 210, a tube 220a, and a filter 220b are sequentially arranged and wrapped by a final wrapper 240a. In FIG. 5, individual wrappers 240b, 240c, 240d, and 240e respectively surround the cross tube 205, the tobacco rod 210, the tube 220a, and the filter 220b, and the final wrapper 240a that wraps around the cross tube 205, the tobacco rod 210, the tube 220a, and the filter 220b respectively surrounded by the individual wrappers 240b, 240c, 240d, and 240e.

The first part described above with reference to FIGS. 1 and 2 includes the cross tube 205 and the tobacco rod 210, and the second part includes the filter 220b. For convenience of description, the following description will be made with reference to FIGS. 1 and 2, and the same description given above with reference to FIG. 4 will be omitted.

The cross tube 205 refers to a tube in the form of a cross, which is connected to the tobacco rod 210.

When the cigarette 200 is inserted into an aerosol-generating device, the cross tube 205 and the tobacco rod 210 may be sensed by a cigarette detection sensor. The cross tube 205 may be wrapped with a copper laminating paper wrapper which also wraps the tobacco rod 210, and may be used for the cigarette detection sensor to determine whether the cigarette 200 inserted is supported by the aerosol-generating device (e.g., whether the cigarette and the aerosol-generating device are manufactured by the same company).

The tobacco rod 210 includes an aerosol-generating material that is heated by the heater 130 of the aerosol-generating device 10 and generates an aerosol.

The tube 220a performs a function of transferring, to the filter 220b, an aerosol generated from the aerosol-generating material of the tobacco rod 210. The tube 220a be manufactured by adding triacetin (TA), i.e., a plasticizer, to cellulose acetate tow and molding the triacetin (TA) into a circle. When compared with the cross tube 205, the tube 220a has a different shape and arranged differently in that the tube 220a connects the tobacco rod 210 and the filter 220b.

When an aerosol generated by the tobacco rod 210 is delivered to the filter 220b through the tube 220a, the filter 220b passes the aerosol to allow a user to inhale the aerosol filtered by the filter 220b. The filter 220b may be a cellulose acetate filter manufactured based on cellulose acetate tow.

The final wrapper 240a is a paper surrounding each of the cross tube 205, the tobacco rod 210, the tube 220a, and the filter 220b, and may include a cross tube wrapper 240b, a tobacco rod wrapper 240c, a tube wrapper 240d, and a filter wrapper 240e.

In FIG. 5, for example, the cross tube wrapper 240b may include an aluminum material. The tube wrapper 240d surrounding the tube 220a may be a MFW or 24K wrapper, and the filter wrapper 240e surrounding the filter 220b may be an oil-resistant hard wrapper or a laminating paper having a poly lactic acid (PLA) material. The tobacco rod wrapper 240c and the final wrapper 240a will be described in more detail below.

The tobacco rod wrapper 240c surrounds the tobacco rod 210, and may be coated with a thermal conductivity improving material in order to maximize the efficiency of thermal energy transfer from the heater 130. For example, the tobacco rod wrapper 240c may be manufactured in a way that a general wrapper or a release base paper is coated with at least one of silver (Ag) foil paper, aluminum (Al) foil paper, copper (Cu) foil paper, carbon paper, filler, ceramic (e.g., AlN or Al₂O₃), silicon carbide, sodium citrate (e.g., Na citrate), potassium citrate (e.g., K citrate), aramid fiber, nano cellulose, mineral paper, glassine paper, and single-walled carbon nanotube (SWNT). The general wrapper refers to a wrapper widely used in cigarettes in the market, and may be a porous wrapper made of a material that has been tested for hand-made paper and has at least a certain level of paper manufacturing workability and thermal conductivity.

In addition, in the present disclosure, the final wrapper 240a may be manufactured in such a way that an MFW base paper is coated with at least one of filler, ceramic, silicon carbide, sodium citrate, potassium citrate, aramid fiber, nano cellulose, and SWNT, among various materials used for coating the tobacco rod wrapper 240c.

The heater 130 included in the externally heating-type aerosol-generating device 10 described with reference to FIGS. 1 and 2 is controlled by the controller 110 and heats the aerosol-generating material included in the tobacco rod 210 to generate an aerosol. In this case, thermal energy transferred to the tobacco rod 210 may be composed of 75% radiant heat, 15% convective heat, and 10% conduction heat. Depending on embodiments, the proportions of radiant heat, convective heat, and conduction heat constituting the thermal energy transferred to the tobacco rod 210 may vary.

In a case where the heater 130 does not directly contact the aerosol-generating material, it may be difficult to rapidly generate an aerosol. In this regard, according to an embodiment, a thermal conductivity improving material may be used for coating the tobacco rod wrapper 240c and the final wrapper 240a such that thermal energy may be efficiently transferred to the aerosol-generating material of the tobacco rod 210. Accordingly, a sufficient amount of aerosol may be provided to a user even during an initial puff before the heater 130 is sufficiently heated.

According to an embodiment, the thermal conductivity improving material may be used for coating only one of the tobacco rod wrapper 240c and the final wrapper 240a. Also, a material having at least a certain level of thermal conductivity, such as organic metal, inorganic metal, fiber, or polymeric material, may be used for coating the tobacco rod wrapper 240c or the final wrapper 240a.

FIG. 6 is a view illustrating an example of the double medium cigarette 300 used in the aerosol-generating device 10 of FIG. 3.

The double medium cigarette in FIG. 6 is different from the cigarettes shown in FIGS. 4 and 5 in that the aerosol generating material and the tobacco material are included in separate portions of the cigarette.

Referring to FIG. 6, the double medium cigarette 300 may have a structure in which an aerosol base portion 310, a medium portion 320, a cooling portion 330, and a filter portion 340 are sequentially arranged and wrapped by a final wrapper 350. In FIG. 6, the final wrapper 350 refers to an outer shell that surrounds individual wrappers 310a, 320a, and 340a which respectively surround the aerosol base portion 310, the medium portion 320, and the filter portion 340.

The aerosol base portion 310 may be made of pulp-based paper to which a moisturizing agent is added. The moisturizing agent (i.e., a basic material) contained in the aerosol base portion 310 may include propylene glycol and glycerin, which have a certain weight ratio with respect to the weight of a base paper. When the double medium cigarette 300 is inserted into the aerosol-generating device 10 of FIG. 3, the aerosol base portion 310 may generate moisturizing agent vapor when heated to or above a certain temperature.

The medium portion 320 includes at least one of a sheet, a strand, and pipe tobacco obtained by cutting a tobacco sheet into small pieces, and generates nicotine to provide a smoking experience to a user. The medium portion 320 may not be directly heated from the heater 130 even though the double medium cigarette 300 is inserted into the aerosol-generating device 10 of FIG. 3. Instead, the medium portion 320 may be indirectly heated by conduction, convection and radiation through the aerosol base portion 310 and a medium portion wrapper 320a (or a final wrapper 350) surrounding the medium portion 320, when they are heated. Specifically, the medium contained in the medium portion 320 needs to be heated to a lower temperature than the moisturizing agents contained in the aerosol base portion 310. In this regard, according to an embodiment, the medium portion 320 may be indirectly heated by the aerosol base portion 310 rather than by the heater 130 that is an external heating type heater. When the temperature of a medium included in the medium portion 320 rises to a temperature above a certain level, nicotine vapor is generated from the medium portion 320.

According to an embodiment, when the double medium cigarette 300 is inserted into the aerosol-generating device 10 of FIG. 3, a portion of the medium portion 320 may be positioned to face the heater 130 and thus may be directly heated by the heater 130.

The cooling portion 330 may be made of a tube filter containing a plasticizer having a certain weight. The moisturizing agent vapor and the nicotine vapor respectively generated from the aerosol base portion 310 and the medium portion 320 may be mixed and aerosolized, and then may be cooled while passing through the cooling portion 330. The cooling portion 330 may not be wrapped with an individual wrapper, unlike the aerosol base portion 310, the medium portion 320, or the filter portion 340.

The filter portion 340 may be a cellulose acetate filter, and the shape of the filter portion 340 is not limited. The filter portion 340 may be a cylinder-type type rod or a tube-type rod including a hollow therein. When the filter portion 340 is composed of a plurality of segments, at least one of the plurality of segments may be manufactured to have a different shape. The filter portion 340 may be manufactured to generate flavor. As an example, a flavoring liquid may be injected into the filter portion 340, and a separate fiber to which a flavoring liquid is applied may be inserted into the filter portion 340.

In addition, at least one capsule may be included in the filter portion 340. In this case, the capsule may perform a function of generating flavor. For example, the capsule may have a structure in which a liquid containing a fragrance is wrapped with a film, and may have a spherical or cylindrical shape, but is not limited thereto.

The final wrapper 350 may refer to an outer shell that wraps, as one element, the aerosol base portion 310, the medium portion 320, and the filter portion 340, respectively surrounded by individual wrappers 310a, 320a, and 340a. The final wrapper 350 may include the same material as the medium portion wrapper 320a.

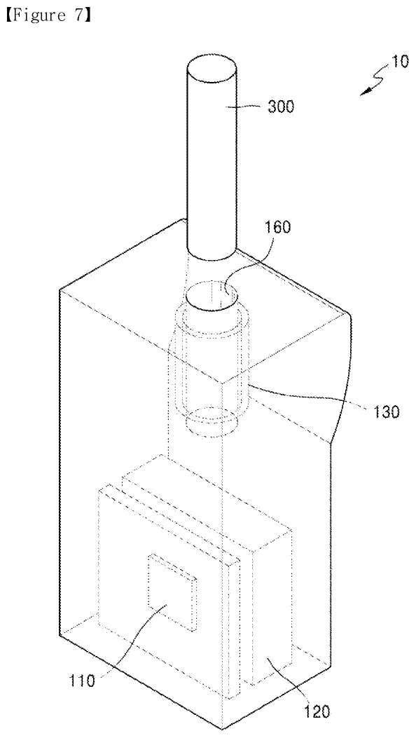

FIG. 7 is a perspective view of an example of an aerosol-generating device 10 according to an embodiment of the present disclosure.

Referring to FIG. 7, the aerosol-generating device 10 according to an embodiment of the present disclosure may include a controller 110, a battery 120, and a heater 130. The double medium cigarette 300 may be inserted into and heated by the aerosol-generating device 10 to generate an aerosol. For convenience of description, only some components of the aerosol-generating device 10 are highlighted and shown in FIG. 7. Thus, the aerosol-generating device 10 may include additional components without departing from the scope of the present disclosure.

In addition, the internal structure of the aerosol-generating device 10 is not limited to that shown in FIG. 7, and according to embodiments or designs, the arrangements of the controller 110, the battery 120, the heater 130, and the double medium cigarette 300 may vary. A description of each component of FIG. 7 will be omitted because it has already been described with reference to FIGS. 1 to 3.

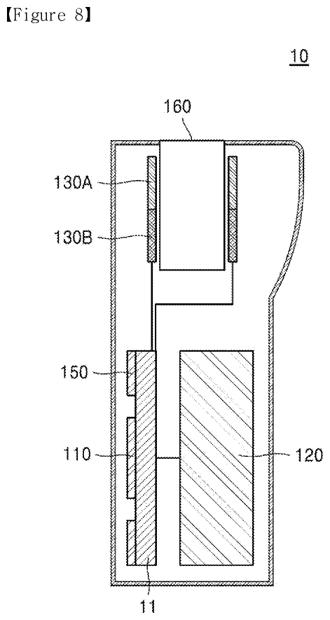

FIG. 8 is a side view of the aerosol-generating device 10 described with reference to FIG. 7.

Referring to FIG. 8, the aerosol-generating device 10 according to an embodiment of the present disclosure may include a printed circuit board (PCB) 11, a controller 110, a battery 120, a first heater 130A, a second heater 130B, a display 150, and a cigarette insertion space 160. Hereinafter, the same description provided above with reference to FIG. 1 will be omitted.

The PCB 11 may perform a function of electronically integrating various components that collect information of the aerosol-generating device 10 while communicating with the controller 110. The controller 110 and the display 150 may be fixedly mounted on the surface of the PCB 11, and the battery 120 for supplying power to devices connected to the PCB 11 may be connected to the surface of the PCB 11.

The first heater 130A and the second heater 130B respectively heat two medium portions of the double medium cigarette 300 to different temperatures, while the double medium cigarette 300 is inserted into the cigarette insertion space 160 of the aerosol-generating device of FIG. 8. The first heater 130A and the second heater 130B may be heated to different temperatures by including different materials, or by receiving different control signals from the controller 110 while including the same material.

The display 150 is a device for outputting visual information to a user, from among information generated by the aerosol-generating device 10. The display 150 may control, based on information received from the controller 110, information output to a display panel (e.g., liquid crystal display (LCD) panel or a light-emitting diode (LED) panel) provided on the front of the aerosol-generating device 10.

The cigarette insertion space 160 refers to a space for receiving the cigarette 200 or the double medium cigarette 300. The cigarette insertion space 160 may have a cylindrical shape so that the cigarette 200 or the double medium cigarette 300, which has the form of a stick, is stably mounted therein, and the height (depth) of the cigarette insertion space 160 may vary depending on the length of a region including an aerosol-generating material in the cigarette 200 or the double medium cigarette 300.

For example, when the double medium cigarette 300 described with reference to FIG. 6 is inserted into the cigarette insertion space 160, the height of the cigarette insertion space 160 may be equal to the sum of the length of the aerosol base portion 310 and the length of the medium portion 320. When the cigarette 200 or the double medium cigarette 300 is inserted into the cigarette insertion space 160, the first heater 130A and the second heater 130B, which are adjacent to the cigarette insertion space 160, may be heated, and thus aerosols may be generated.

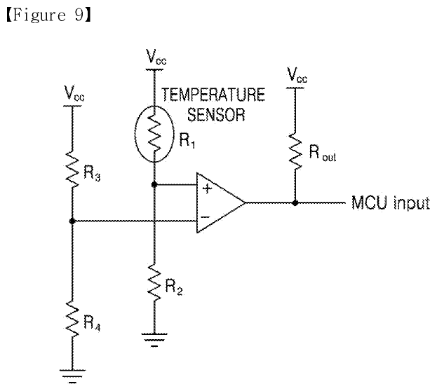

FIG. 9 is a view illustrating an example of a puff recognition circuit included in an aerosol-generating device according to an embodiment of the present disclosure.

Referring to FIG. 9, the puff recognition circuit included in the aerosol-generating device according to an embodiment of the present disclosure includes a comparator and a plurality of resistors, The output signal of the comparator is input to a microcontroller unit (MCU) that is a controller. Hereinafter, it is assumed that a temperature sensor includes a temperature change sensing portion installed in an airflow path formed inside the aerosol generating device such that the temperature change sensing portion is directly exposed to the air flowing in the airflow path, and a variable resistance portion (or a variable resistor) having resistance that is agilely changed according to a temperature change sensed by the temperature change sensing portion. Unless otherwise specified, a resistor of the temperature sensor is regarded as having the same meaning as the variable resistance portion.

First, an input voltage of the positive (+) terminal of the comparator is determined based on a driving voltage Vcc of the comparator, a variable resistor R1 of the temperature sensor, and a resistor R2 having fixed resistance.

$${V}_{+} = \frac{{R}_{2}}{{R}_{1} + {R}_{2}} {V}_{CC} \qquad [ Equation 1 ]$$

Equation 1 is an expression of the input voltage V+ of the positive (+) terminal of the comparator. Other variables constituting Equation 1 have already been described above.

Voltages are applied to the resistors R1 and R2 in proportion to the resistance values of the resistors R1 and R2, respectively. Because the resistor R1 of the temperature sensor is a variable resistor, the voltage applied to the resistor R1 also varies with the resistance of the resistor R1, and the input voltage of the positive (+) terminal of the comparator is also affected by the resistance of the resistor R1.

The resistor R1 of the temperature sensor may be one of a Negative Temperature Coefficient of Resistance (NTC) device and a Positive Temperature Coefficient of Resistance (PTC) device. As an example, when the resistor R1 of the temperature sensor is an NTC device and the temperature change sensing portion of the temperature sensor senses the temperature rise of the air in the airflow path, the resistance of the resistor R1 changes in inverse proportion to the sensed temperature rise. As a result, the input voltage V+ of the positive (+) terminal becomes larger than before the temperature change is sensed. As another example, when the resistor R1 of the temperature sensor is a PTC device and the temperature change sensing portion of the temperature sensor senses a temperature rise of the air in the airflow path, the resistance of the resistor R1 changes in proportion to the sensed temperature rise. As a result, the input voltage V+ of the positive (+) terminal becomes smaller than before the temperature change is sensed.

The resistor R2 has a constant resistance, and the resistance values of the resistor R2 and the resistor R1 affect the input voltage V+ of the positive (+) terminal of the comparator. According to Equation 1, when the resistor R2 has an excessively larger value than the resistor R1, the change in the resistance of the resistor R1 is ignored and the sensitivity of the input voltage V+ of the positive (+) terminal is lowered. Thus, the resistor R2 may be selected to have a resistance value similar to that of the resistor R1 in a certain range.

Furthermore, an input voltage of the negative (−) terminal of the comparator of FIG. 9 is determined based on the driving voltage Vcc of the comparator and the fixed resistance values of resistors R3 and R4.

$${V}_{-} = \frac{{R}_{4}}{{R}_{3} + {R}_{4}} {V}_{CC} \qquad [ Equation 2 ]$$

Equation 2 is an expression of the input voltage of the negative terminal of the comparator. In Equation 2, V− refers to the input voltage of the negative terminal (−) of the comparator.

Voltages are applied to the resistors R3 and R4 in proportion to the resistance values of the resistors R3 and R4, respectively. Because both the resistor R3 and the resistor R4 have constant resistance values, the input voltage of the negative (−) terminal of the comparator is proportional to the driving voltage Vcc of the comparator. Because the driving voltage Vcc of the comparator is maintained constant, the input voltage of the negative (−) terminal may be fixed to a preset value.

The comparator compares the input voltage V+ of the positive (+) terminal with the input voltage V− of the negative (−) terminal. When the input voltage V+ of the positive (+) terminal is greater than the input voltage V− of the negative (−) terminal, a certain signal is outputted through the output terminal of the comparator to the MCU (the controller). In this case, the MCU may detect that the input signal thereof is changed from a low signal to a high signal, and determine that a puff has occurred through the aerosol-generating device.

Hereinafter, for convenience of description, the input voltage of the positive (+) terminal of the comparator will be referred to as first information, and the input voltage of the negative (−) terminal of the comparator will be referred to as second information.

As described in Equations 1 and 2, the first information and the second information change in proportion to the driving voltage Vcc that is used to drive a certain module (e.g., comparator) included in the aerosol-generating device. Because the first information depends on the variable resistance of the temperature sensor and the variable resistance depends on the temperature change sensed by the temperature sensor, the first information may be understood as information representing a temperature change of the air in the airflow path.

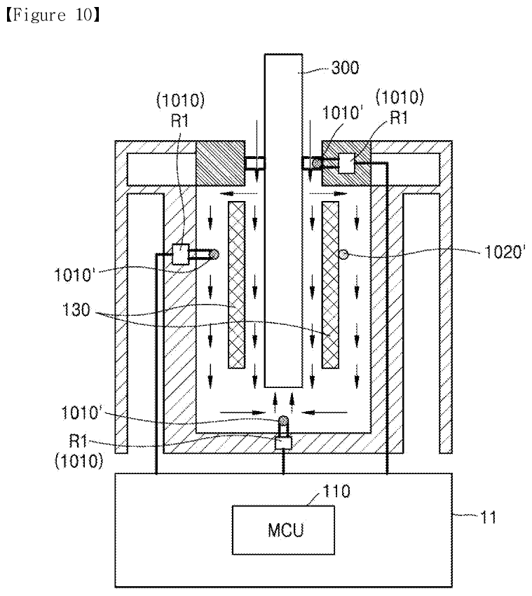

FIG. 10 is a schematic view illustrating a cross-section of an aerosol-generating device according to an embodiment of the present disclosure.

FIG. 10 is a diagram illustrating where the temperature sensor is positioned and how puff recognition of the MCU (the controller) is implemented in the aerosol-generating device according to an embodiment of the present disclosure. In the center of FIG. 10, the double medium cigarette 300 shown in FIG. 6 is inserted into a cigarette insertion space, and the airflow occurring by a user's inhalation action is indicated by arrows around the cigarette insertion space.

As described above with reference to FIG. 9, the temperature sensor in FIG. 10 includes a temperature change sensing portion 1010′ that is completely exposed to the airflow path to come into direct contact with the air inside the airflow path, and capable of sensing a change in temperature. Also, the temperature sensor includes a variable resistor R1 (1010) having resistance that varies depending on a temperature change sensed by the temperature change sensing portion 1010′. The variable resistor R1 may also serve to fix the position of the temperature change sensing portion 1010′. As shown in FIG. 10, a temperature sensor 1020′ for monitoring the temperature change may also be installed at a heater 130 for heating the double medium cigarette 300. However, the temperature sensor installed at the heater 130 may not output information necessary to recognize a puff.

In addition, it is illustrated that temperature sensors are installed at four locations in FIG. 10. However, the number of temperature sensors is not limited to a certain number. According to embodiments, the number of temperature sensors may be different from that shown in FIG. 10. In addition, the temperature sensor installed in the airflow path may selectively sense only a temperature change greater than or equal to a preset value, thereby further improving the reliability of puff recognition.

In FIG. 10, when the aerosol-generating device is turned on and preheating of the heater 130 is completed, the temperature of the air in the airflow path is also stabilized to be constant. In this case, the temperature sensors installed in the airflow path use, as a reference, the temperature of stabilized air after the preheating of the heater 130 is completed, sense a temperature change of the air whenever the temperature of the air in the airflow path is temporarily lowered by a user's puff, and changes the resistance of the variable resistor 1010, so that the MCU 110 of the PCB 11 may recognize that a puff has occurred.

Referring FIGS. 9 and 10, a puff recognition circuit for accurately recognizing a user's puff in the aerosol-generating device according to an embodiment of the present disclosure may include a comparator, a resistor, an MCU, etc. Among these components, a variable resistor and a temperature change sensing portion, which are essential for composing the input voltage of the positive terminal of the comparator, are installed in the airflow path, and the remaining components are mounted on the PCB 11.

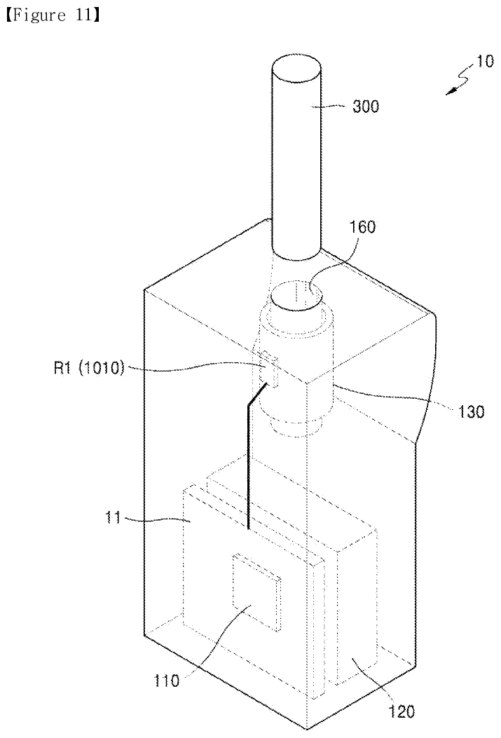

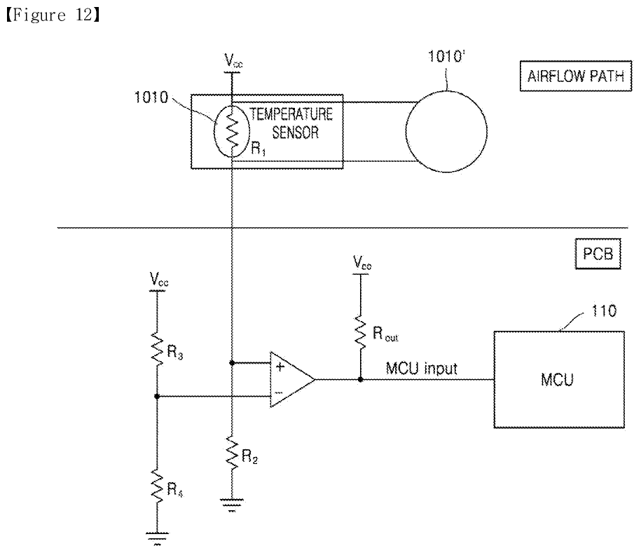

FIG. 11 is a perspective view of another example of an aerosol-generating device according to an embodiment of the present disclosure Referring to FIG. 11, it may be seen that a variable resistor R1 (1010) is installed close to a cigarette insertion space 160 or a heater 130 surrounding the cigarette insertion space 160. Although the temperature change sensing portion 1010′ is omitted for intuitive understanding of the drawing, it will be apparent to those skilled in the art that the temperature change sensing portion 1010′ may be located close to the variable resistor R1 (1010) in an actual implementation example.

In order for the resistance change of the variable resistor R1 (1010) to be immediately reflected, the variable resistor R1 (1010) may be electrically connected to the PCB 11 located at the bottom of the aerosol-generating device through a wire, and the controller 110 may receive a certain input signal from a comparator mounted on the PCB 11 and recognize that a user's puff has occurred.

FIG. 12 is a diagram for more intuitively illustrating the puff recognition circuit described with reference to FIGS. 9 to 11.

FIG. 12 shows a puff recognition circuit that is included and driven in the aerosol-generating device. The variable resistor R1 (1010) and the temperature change sensing portion 1010′, installed in the airflow path, are shown in an upper part of FIG. 12. Also, the comparator, the MCU 110, the remaining resistors except for the resistor R1, mounted on the PCB, are shown in a lower part of FIG. 12.

As described with reference to FIGS. 9 to 11, when a temperature change of the air in the airflow path is detected, the detection result is converted into a resistance value change. Then, the comparator outputs a signal based on the resistance value change, and the MCU 110 recognizes a puff based on the signal received from the comparator.

As described with reference to FIG. 10, according to embodiments, a puff recognition circuit may be expanded to include two or more temperature sensors.

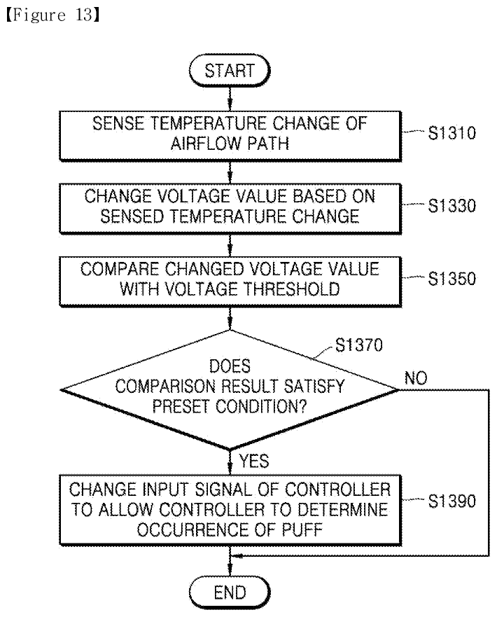

FIG. 13 is a flowchart illustrating an example of a puff recognition method of an aerosol-generating device according to an embodiment of the present disclosure.

The puff recognition method of FIG. 13 may be implemented through the aerosol-generating device having a puff recognition function, described with reference to FIGS. 9 to 12. Hereinafter, the puff recognition method will be described with reference to FIGS. 9 to 12, and the same descriptions given above will be omitted. In addition, unless specifically limited, the temperature sensor is regarded as a general term for a combined configuration of the temperature change sensing portion 1010′ and the variable resistance portion 1010.

The temperature sensor installed in the airflow path senses a temperature change of the airflow path (operation S1310).

The resistance of the temperature sensor installed in the airflow path is changed based on the sensed temperature change, and accordingly, a voltage value applied to the temperature sensor is also changed (operation S1330).

The comparator compares the changed voltage value with a voltage threshold (operation S1350) and determines whether the comparison result satisfies a preset condition (operation S1370). In operation S1350, the changed voltage value may be the first information described above, and the voltage threshold may be the second information described above. In addition, in operation S1370, satisfying the preset condition means a comparison result in which the changed voltage value is greater than the voltage threshold.

When the comparison result satisfies the preset condition in operation S1370, the comparator changes a “Low” signal output as the input signal of the controller to a “High” signal (operation S1390). The controller receiving the “Low” signal may determine that a user's puff has occurred after receiving the “High” signal.

According to the present disclosure, a puff (i.e., inhalation) may be accurately recognized regardless of the intrinsic characteristics of a user's inhalation action.

In addition, according to the present disclosure, the number of puffs may be counted accurately, and thus a consistent aerosol quality may be maintained.

The embodiments of the present disclosure may be implemented in the form of a computer program which may be executed on a computer via various types of components, and such a computer program may be recorded on a computer-readable recording medium. The medium may include a magnetic medium such as a hard disk, a floppy disk, and a magnetic tape, an optical recording medium such as CD-ROM and DVD, a magneto-optical medium such as a floptical disk, and a hardware device specifically configured to store and execute program instructions, such as ROM, RAM, and flash memory.

The computer program is specifically designed and configured for the present disclosure but may be known to and used by one of ordinary skill in the computer software field. Examples of the computer program may include a high-level language code which may be executed using an interpreter or the like by a computer, as well as a machine language code such as that made by a complier.

The specific implementations described in the present disclosure are example embodiments and do not limit the scope of the present disclosure in any way. For brevity of the specification, descriptions of existing electronic configurations, control systems, software, and other functional aspects of the systems may be omitted. Connections of lines or connection members between components illustrated in the drawings illustratively show functional connections and/or physical or circuit connections and may be represented as alternative or additional various functional connections, physical connections, or circuit connections in an actual device. Unless specifically mentioned, such as “essential”, “importantly”, etc., the components may not be necessary components for application of the present disclosure.

As used herein (in particular, in claims), use of the term “the” and similar indication terms may correspond to both singular and plural. When a range is described in the present disclosure, the present disclosure may include the invention to which individual values belonging to the range are applied (unless contrary description), and each individual value constituting the range is the same as being described in the detailed description of the disclosure. —Unless there is an explicit description of the order of the steps constituting the method according to the present disclosure or a contrary description, the steps may be performed in an appropriate order. The present disclosure is not necessarily limited to the description order of the steps. The use of all examples or example terms (for example, etc.) is merely for describing the present disclosure in detail, and the scope of the present disclosure is not limited by the examples or the example terms unless the examples or the example terms are limited by claims. It will be understood by one of ordinary skill in the art that various modifications, combinations, and changes may be made according to the design conditions and factors within the scope of the appended claims or equivalents thereof.

1. An aerosol-generating device comprising:
a temperature sensor configured to sense a temperature change of an airflow path formed inside the aerosol-generating device; and
a controller configured to compare first information that varies depending on the temperature change with preset second information when the temperature change is sensed, and determine whether a user's puff occurred based on a comparison result.

2. The aerosol-generating device of claim 1, wherein the first information and the second information change in proportion to a driving voltage of a first module included in the aerosol-generating device.

3. The aerosol-generating device of claim 2, wherein the first module includes a comparator.

4. The aerosol-generating device of claim 3, wherein the first information includes an input voltage of a positive (+) terminal of the comparator, and the second information includes an input voltage of a negative (−) terminal of the comparator, and
wherein the controller is further configured to determine that the user's puff occurred, based on a signal that is output from an output terminal of the comparator when the input voltage of the positive (+) terminal is greater than the input voltage of the negative (−) terminal.

5. The aerosol-generating device of claim 1, wherein the first information includes a voltage value that changes according to the temperature change of the airflow path.

6. The aerosol-generating device of claim 1, wherein the temperature sensor includes a temperature change sensing portion configured to sense the temperature change, and a variable resistor having a resistance that changes in proportion to the temperature change.

7. The aerosol-generating device of claim 1, wherein the temperature sensor includes a temperature change sensing portion configured to sense the temperature change, and a variable resistor having a resistance that changes in inverse proportion to the temperature change.

8. The aerosol-generating device of claim 1, wherein the second information is determined based on constant resistance values of two resistors.

9. The aerosol-generating device of claim 1, wherein two or more temperature sensors are provided in the aerosol-generating device, and the first information is calculated based on temperature changes sensed by the two or more temperature sensors.

10. The aerosol-generating device of claim 1, wherein the temperature sensor is further configured to selectively sense a temperature change exceeding a preset value.

11. A puff recognition method of an aerosol-generating device, the puff recognition method comprising:
sensing, by a temperature sensor, a temperature change of air in an airflow path formed inside the aerosol-generating device;
comparing, by a first module, first information that varies depending on the temperature change with preset second information when the temperature change is sensed; and
determining, by a controller, whether a user's puff occurred based on a result of the comparing.

12. The puff recognition method of claim 11, wherein the first information and the second information change in proportion to a driving voltage of the first module.

13. The puff recognition method of claim 12, wherein the first module includes a comparator.

14. The puff recognition method of claim 13, wherein the first information includes an input voltage of a positive (+) terminal of the comparator, and the second information includes an input voltage of a negative (−) terminal of the comparator, and
wherein the determining of whether the user's puff occurred includes determining that the user's puff occurred, based on a signal that is output from an output terminal of the comparator when the input voltage of the positive (+) terminal is greater than the input voltage of the negative (−) terminal.

15. The puff recognition method of claim 11, wherein the first information is calculated based on temperature changes sensed by two or more temperature sensors.
